(19) United States
(12) Patent Application Publication
(10) Pub. No.: US 2020/0373945 A1
(43) Pub. Date: Nov. 26, 2020

(54) RATE MATCHING IN POLAR CODES

(71) Applicant: NEC CORPORATION, Tokyo (JP)

(72) Inventors: Prakash CHAKI, Tokyo (JP); Norifumi KAMIYA, Tokyo (JP)

(73) Assignee: NEC CORPORATION, Tokyo (JP)

(21) Appl. No.: 16/637,199

(22) PCT Filed: Aug. 10, 2017
(86) PCT No.: PCT/JP2017/029167

§ 371 Date: Feb. 6, 2020

(51) Int. Cl. H03M 13/00; H03M 13/15

(52) U.S. Cl. CPC H03M 13/635; H03M 13/155

(57) ABSTRACT

A communication apparatus includes: an encoder that encodes an input vector to output a codeword of polar code; a memory that stores a reliability-ordered sequence of indices of the input vector and a set of indices for rate-matching; a controller that is configured to: select a frozen set of indices based on at least one of a universal rate-matching scheme and the reliability-ordered sequence stored in the memory such that the reliability-ordered sequence is generated without considering the rate-matching scheme; construct the input vector by setting the frozen set to a frozen bit and a non-frozen set to information bits; and skip codebits of the codeword outputted by the encoder from transmission, the codebits corresponding respectively to the set of indices for rate-matching.

### TECHNICAL FIELD

The present invention relates to a communication apparatus using polar codes, and particularly to rate-matching in polar codes.

### BACKGROUND

Polar codes introduced in NPL 1 are the first family of provably capacity-achieving codes in Binary-Input Discrete Memoryless Symmetric (BI-DMS) class of channels. Polarization is a linear transform that converts N copies of a BI-DMS channel into one of the two extremes, i.e., bit-channels with very low error probabilities (very high capacities) or bit-channels with very high error probabilities (very low capacities), where N is length of polar codeword. It has been shown that for very large N (asymptotic case), the fraction of bit-channels with low error probabilities approaches the capacity of the underlying BI-DMS channel. Encoding of (N, K) polar codes involve:
putting information bits at the K indices out of N indices with relatively low error probabilities (also called Non-Frozen (NF) set) and putting a constant bit pattern (such as all-zero pattern) at the remaining N-K indices with higher error probabilities; and then
multiplying the resulting vector with a bit-reversal permutation matrix B and the generator matrix which may be n-times Kronecker product of a 2×2 matrix G₂.

$${G}_{2} = ( \begin{matrix}1 & 0 \\ 1 & 1\end{matrix} ) , \qquad ( Math . 1 )$$

referred to as the polarizing kernel. The resulting codeword is then transmitted.

The decoder at the receiver side may compute the log-likelihood ratios (LLRs) from the received values of channel output, use the LLR values as input to the decoder and perform decoding to output the estimated information vector. Successive Cancellation (SC) decoder introduced in NPL 1 is the most fundamental decoder for polar codes. SC List decoder (SCL) and Cyclic Redundancy Check (CRC)-aided SCL (CA-SCL) decoders have been introduced subsequently to boost up the decoding performance (see NPL 2). NPL 3 introduces a method for using Density Evolution (DE) with Gaussian Approximation (GA) in the context of polar code encoding and decoding.

Since polar codes have lengths which are powers of two, rate-matching is required to vary the coding rate of polar codeword depending on channel condition or to match the rates of transport block and physical layer frame. A rate-matched polar code which is a polar-code codeword of any desired code length and rate may be constructed by employing a scheme such as puncturing, shortening or repetition. Puncturing is a method that refers to removing some of the bits from the codeword before transmission. Thus, it is possible to construct a codeword of length M from a codeword of length N=2ⁿ by puncturing N-M bits, where 2ⁿ⁻¹<M<2ⁿ. The punctured positions are not known to the decoder in advance. Alternatively, shortening is a method that refers to setting one or more input bits to some known value (e.g. 0) such that one or more codebits have a known value (e.g., 0); these known codebits are then not transmitted. The non-transmitted codebits are known to the decoder in advance.

### CITATION LIST

### Non Patent Literature

[NPL 1]
   E. Arikan, “Channel polarization: A method for constructing capacity-achieving codes for symmetric binary-input memoryless channels”, IEEE Transactions of Information Theory, vol. 55, pp. 3051-3073, July 2009.
[NPL 2]
   I. Tal and A. Vardy, “List decoding of polar codes”, IEEE Transactions of Information Theory, vol. 61, no. 5, pp. 2213-2226, May 2015.
[NPL 3]
   P. Trifonov, “Efficient design and decoding of polar codes”, IEEE Transactions on communications, vol. 60, no. 11, November 2012.

### SUMMARY

### Technical Problem

A key problem in rate-matched polar codes is that the sequence design (i.e. the reliability-based ordering of the indices) may be changed after rate-matching is applied. For instance, since the punctured positions are not known to the decoder in advance, the decoder sets the initial values of the LLR corresponding to the untransmitted codebit positions to 0 and then starts decoding. This in turn has implications on the reliabilities of the indices in the input vector to the encoder. Specifically, the reliability values and/or reliability-based ordering of the indices may alter from the values computed without rate-matching consideration. In other words, the pre-stored sequence designed for non-rate-matched polar codes may be of no use for designing rate-matched polar codes. If the sequence for non-rate-matched polar codes is used for designing rate-matched polar codes, degradation in error correcting performance of the resulting rate-matched polar code may be observed. Accordingly, to design a rate-matched (e.g., punctured or shortened) polar code the reliability based ordering of indices (referred to as “sequence design” in the present document) has to be generated based on the rate-matching scheme and parameters. Thus sequence design cannot be done at first independently of rate-matching scheme; rather rate-matching scheme and parameters have to be taken into account for sequence design. Hence, if the rate-matching parameters (e.g., number of punctured bits, positions of punctured bits) are changed, a different reliability ordered sequence may be necessary.

On the other hand, if rate-matching scheme is decided at first and then sequence is designed based on rate-matching scheme, then multiple sequences may have to be designed corresponding to each value of M. Further, multiple sequences may have to be designed corresponding to each of rate-matching schemes (puncturing, shortening, repetition etc.) and their patterns (natural order, bit-reversal order, etc.).

As described above, if the sequence design and the rate-matching are done independently, it becomes necessary to construct a new reliability-ordered sequence optimized to a specific rate-matching scheme for improved performance in rate-matched polar codes. In other words, the rate-matched polar codes, if designed using a reliability ordered sequence which is not optimized to the rate-matching scheme, the pattern and the number of non-transmitted bits, may show degraded error correcting performance. Accordingly, for rate-matched polar codes, the reliability ordered sequence has to be designed based on the rate-matching pattern.

It should also be understood that a reliability-ordered sequence has to be computed for each value of N-M bits, which makes it a computationally expensive operation. Else, the reliability-ordered sequences can be pre-computed for a given set of values of N-M bits corresponding to a given rate-matching scheme and stored in memory, resulting in increased memory requirement.

An objective of the present invention is to provide a technique for designing rate-matched polar codes at lower implementation complexity.

### Solution to Problem

According to the present invention, a communication apparatus includes: an encoder that encodes an input vector to output a codeword of polar code; a memory that stores a reliability-ordered sequence of indices of the input vector and a set of indices for rate-matching; a controller that is configured to: select a frozen set of indices based on at least one of a universal rate-matching scheme and the reliability-ordered sequence stored in the memory such that the reliability-ordered sequence is generated without considering the rate-matching scheme; construct the input vector by setting the frozen set to a frozen bit and a non-frozen set to information bits; and skip codebits of the codeword outputted by the encoder from transmission, the codebits corresponding respectively to the set of indices for rate-matching.

According to the present invention, a rate matching method for a communication apparatus which comprises: an encoder that encodes an input vector to output a codeword of polar code; and a memory that stores a reliability-ordered sequence of indices of the input vector and a set of indices for rate-matching, the method includes: selecting a frozen set of indices based on at least one of a universal rate-matching scheme and the reliability-ordered sequence stored in the memory such that the reliability-ordered sequence is generated without considering the rate-matching scheme; constructing the input vector by setting the frozen set to a frozen bit and a non-frozen set to information bits; and skipping codebits of the codeword outputted by the encoder from transmission, the codebits corresponding respectively to the set of indices for rate-matching.

According to the present invention, a non-transitory recording medium that stores a program for controlling a communication apparatus which comprises: an encoder that encodes an input vector to output a codeword of polar code; and a memory that stores a reliability-ordered sequence of indices of the input vector and a set of indices for rate-matching, the program comprising a set of instructions to: select a frozen set of indices based on at least one of a universal rate-matching scheme and the reliability-ordered sequence stored in the memory such that the reliability-ordered sequence is generated without considering the rate-matching scheme; construct the input vector by setting the frozen set to a frozen bit and a non-frozen set to information bits; and skip codebits of the codeword outputted by the encoder from transmission, the codebits corresponding respectively to the set of indices for rate-matching.

As described above, according to the present invention, rate-matched polar code system can be designed at lower implementation complexity.

The invention accordingly comprises the several steps and the relation of one or more of such steps with respect to each of the others, and the apparatus embodying features of construction, combinations of elements and arrangement of parts that are adapted to affect such steps, all is exemplified in the following detailed disclosure, and the scope of the invention will be indicated in the claims. In addition to the objects mentioned, other obvious and apparent advantages of the invention will be reflected from the detailed specification and drawings.

### BRIEF DESCRIPTION OF DRAWINGS

FIG. 1 is a schematic diagram illustrating an encoding operation in polar codes according to an exemplary embodiment of the present invention.

FIG. 2 is a flowchart illustrating an operation of reliability-ordered sequence design without considering rate-matching scheme and pattern at the sender device.

FIG. 3 is a flowchart illustrating an operation of reliability-ordered sequence design optimized based on puncturing scheme and pattern at the sender device.

FIG. 4 is a flowchart illustrating an operation of reliability-ordered sequence design optimized based on bit-reversal shortening scheme and pattern at the sender device.

FIG. 5 illustrates BLER-SNR graphs showing universality property of bit-reversal shortening and non-universality of block puncturing.

FIG. 6 is a schematic diagram illustrating a functional configuration of a sender device according to an exemplary embodiment of the present invention.

FIG. 7A is a flowchart illustrating an operation of constructing (M, K) rate-matched polar code at the sender device according to the exemplary embodiment of the present invention.

FIG. 7B is a flowchart illustrating an operation of frozen set selection according to the exemplary embodiment of the present invention.

FIG. 8 is a schematic diagram illustrating a functional configuration of a receiver device according to the exemplary embodiment.

FIG. 9 is a diagram illustrating another architecture of a communication device according to the exemplary embodiment of the present invention.

### DETAILED DESCRIPTION

Hereinafter, the word “exemplary” is used herein to mean “serving as an example, instance, or illustration”. Any embodiment described herein as “exemplary” is not necessarily to be construed as preferred or advantageous over other embodiments.

### 1. Outline of Exemplary Embodiments

The above-discussed technical problems can be solved by one or more variants of the exemplary embodiments of the present invention. In this present disclosure, design of a rate-matched polar code system will be explained. It is assumed that the terms “scheme”, “pattern” and “parameters” used in the present disclosure imply the followings:
Scheme: puncturing, shortening, repetition etc.;
Pattern: natural order, bit-reversal, pseudorandom etc.; and
Parameter: M, K, K/M, wherein M is the number of transmitted codebits (M is not a power of two), and K is the number of information bits.

Bit-reversal order permutation may be understood as the following: If (b_{d}b_{d-1}. . . b₀) be the binary representation of a decimal number x, then the decimal number represented by (b₀. . . b_{d-1}b_{d}) may be regarded as the bit-reversal of x.

### 1.1) Universal Rate-Matching Scheme

A basic procedure for (N, K) polar code encoding is as follows:
Store reliability-based ordering of all N (=2ⁿ) indices;
Divide N indices of input vector U into a frozen set and a non-frozen set based on reliabilities of indices,
Put information bits at the K high reliable indices and frozen bit (e.g. 0) at the N-K low reliable indices to construct an input vector; and
Encode by multiplying the input vector U with a bit-reversal permutation matrix B and the generator matrix

G₂^{⊗n} (Math. 2)

which may be n-times Kronecker product of the polarizing kernel G₂. Thus the encoding operation may be written as

c=uBG₂^{⊗n} (Math. 3)

where c is generated codeword, u is input to the encoder.

When constructing (M, K) rate-matched polar code, however, the reliability ordering of N indices cannot be used normally because the reliability-based ordering may change when puncturing or shortening is considered. As described before, a conventional solution to this problem is to regenerate the sequence based on rate-matching scheme and code parameters.

In contrast, according to a novel solution to the problem, a puncturing or shortening scheme which does not change the reliability ordering of indices significantly is used to construct a rate-matched polar code with at least a single pre-computed sequence. Such a scheme may have a special feature that causes no significant change in sequence design with and without rate-matching consideration. Hereinafter, the scheme having such a special feature is referred to as a universal rate-matching scheme or a universally exploitable rate-matching scheme.

A universal rate-matching scheme can be found by comparing error correcting performance of rate-matched polar code with and without sequence redesign (i.e., using sequence designed for non-rate-matched polar code and using another sequence that is designed based on the used rate-matching scheme) after applying a puncturing or shortening scheme. If the error correcting performance of the rate-matched polar code with and without sequence redesign is very similar to each other or substantially overlaps, the applied scheme can be used as a universal rate-matching scheme. In other words, the universal rate-matching scheme may allow the reliability-based ordering of indices without considering rate-matching to be very similar to that optimized to rate-matching. Accordingly, the same sequence design can be used for non-rate-matched polar codes and can be used even for rate-matched polar codes, resulting in no need of sequence redesign. More details will be described later.

### 1.2) Construction of (M, K) Rate-Matched Polar Code

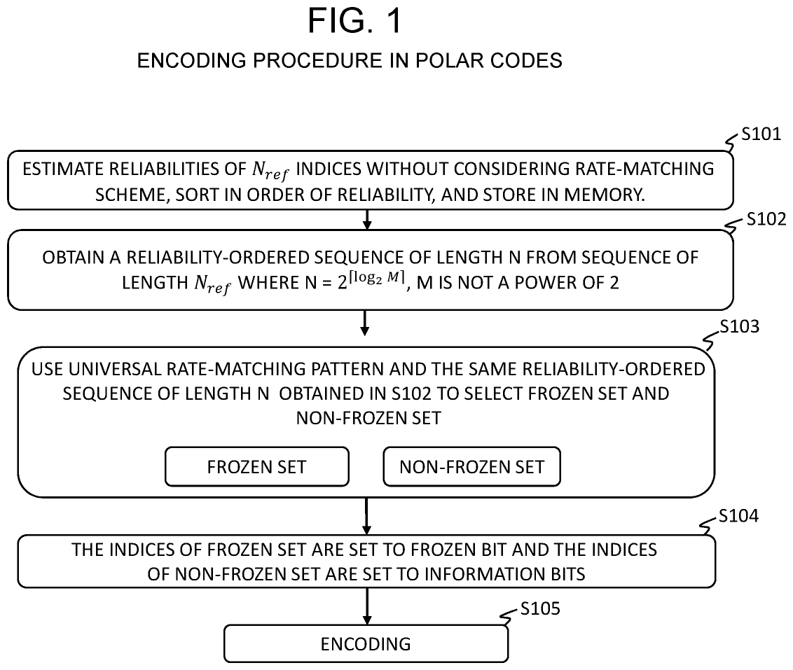

As illustrated in FIG. 1, an encoding procedure in polar codes according to the present invention has the feature that the sequence design can be performed without considering rate-matching, resulting in no need to design a sequence for every change in rate-matching parameter.

More specifically, the encoding procedure for (M, K) rate-matched polar code is as follows:
S101: Estimate reliabilities of N_{ref} indices without considering any rate-matching scheme and sort the indices according to reliability for each index, wherein N_{ref} is 2ⁿ, n is a positive integer and Store this reliability based ordering of N_{ref} indices in memory.
S102: Obtain the reliability-based ordering of N indices of an input vector assuming no rate-matching scheme from the reference sequence N_{ref}, where N can be longer, shorter or of same length as N_{ref}.
S103: Use the universal rate-matching pattern and the reliability-based ordering of N indices obtained in S102 to select a frozen set and a non-frozen set.
S104: Construct the input vector to the encoder of polar code based on the frozen set and the non-frozen set.
S105: Encode by multiplying the input vector with the generator matrix to output a rate-matched codeword. A bit-reversal permutation matrix B may also be multiplied.

### 1.3) Advantages

As described above, by using the universal rate-matching scheme, it is possible to continue using the pre-stored reliability-ordered sequence of indices (that has been generated without considering rate-matching) for selecting the frozen and non-frozen sets of indices. This solves the problem of designing optimized reliability-ordered sequence of indices corresponding to each rate-matching pattern and scheme. Thus the implementation of a rate-matched polar code system becomes significantly simpler.

### 2. Universality Property

### 2.1) Reliability-Ordered Sequence Design

The reliabilities of indices can be calculated by Density Evolution (DE) based on Gaussian Approximation (GA) as explained in NPL 3 but other methods are not precluded. Hereinafter, how the estimation of reliability of each index in the input vector of length N is made (assuming the case that N is same as N_{ref} as an example for ease of understanding) will be described in the following cases: without rate-matching consideration; and with rate-matching consideration (block puncturing, bit-reversal shortening, etc).

<Sequence Design with No Rate-Matching Consideration>

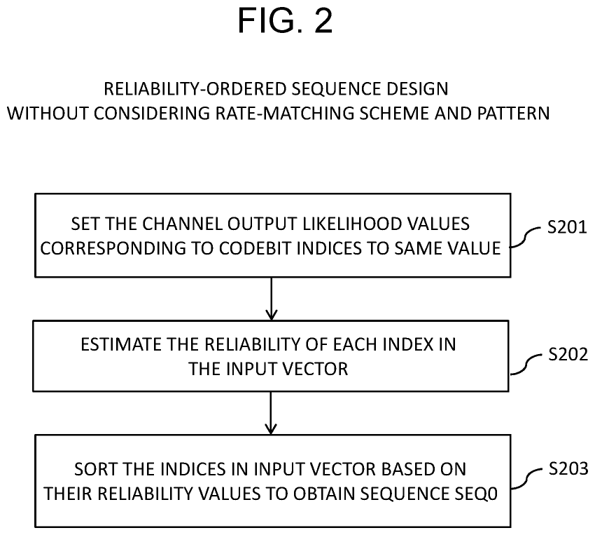

As illustrated in FIG. 2, the reliability values of the bit indices in input vector are estimated without taking into account any rate-matching scheme or pattern. The initial channel output likelihood values corresponding to each codebit index may be set to the same value using the noise variance of the underlying channel (Operation S201), for instance, an Additive White Gaussian Noise (AWGN) channel. The reliabilities of the indices in the input vector can then be estimated using the DE based on GA (Operation S202). The indices are then sorted based on their reliability values to obtain a reliability-based sequence SEQO (Operation S203).

### <Sequence Design for Block Puncturing>

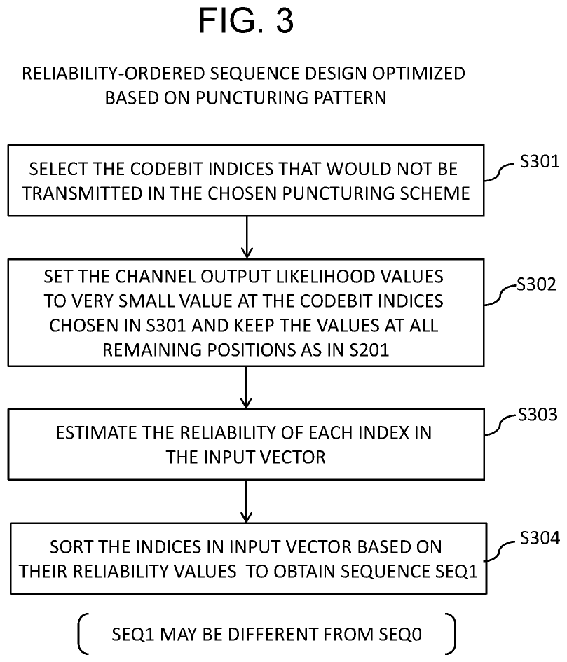

As illustrated in FIG. 3, the reliability values of the bit indices are estimated with block puncturing. First, the codebit indices that would not be transmitted in a chosen puncturing scheme are selected (Operation S301). For instance, a block puncturing scheme may select the codebits with indices which are bit-reversal of the first N-M indices and skip the transmission of these codebits when the encoder is of the form

BG₂^{⊗n}. (Math. 4)

The LLR values at the codebit indices selected in S301 are set to very small value (e.g. 0) and the values at the remaining indices are kept the same value as in S201 (Operation S302). The reliabilities of the indices in the input vector can then be estimated using the DE based on GA (Operation S403). The indices of input vector are then sorted based on their reliability values to obtain a reliability-based sequence SEQ1 (Operation S304). When estimating the reliabilities with block puncturing, the resultant reliability-based sequence SEQ1 may be changed from the reliability-based sequence SEQ0 obtained in the case of no rate-matching consideration. Accordingly, block puncturing shows degraded block error rate (BLER) performance if new reliability ordering is not done.
<Sequence Design with Bit-Reversal Shortening>

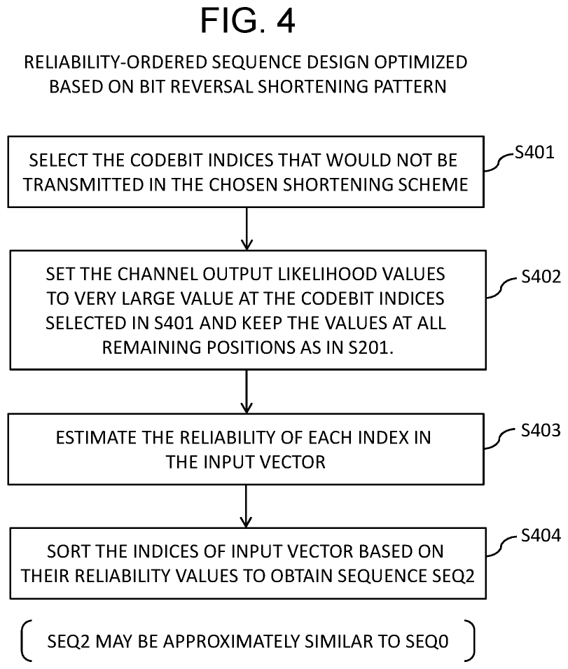

As illustrated in FIG. 4, the reliability values of the bit indices are estimated with bit-reversal shortening. First, the codebit indices that would not be transmitted in a chosen shortening scheme are selected (Operation S401). The channel output likelihood values at the codebit indices selected in S401 are set to very large value (e.g. infinity) and the values at the remaining indices are kept the same value as in S201 (Operation S402). The reliabilities of the indices in the input vector can then be estimated using the DE based on GA (Operation S403). The indices are then sorted based on their reliability values to obtain a reliability-based sequence SEQ2 (Operation S404). When estimating the reliabilities with bit-reversal shortening, the resultant reliability-based sequence SEQ2 may be approximately similar to the reliability-based sequence SEQ0 obtained in the case of no rate-matching consideration. Accordingly, the bit-reversal shortening can be used as a universal rate-matching scheme.

### 2.2) Example of Universal Rate-Matching Scheme

As described above, the bit-reversal shortening may be an example of the universal rate-matching scheme because it has the universality property such that the reliability-based sequence is not changed by much and therefore new reliability ordering of indices optimized for a specific rate-matching scheme may not be required.

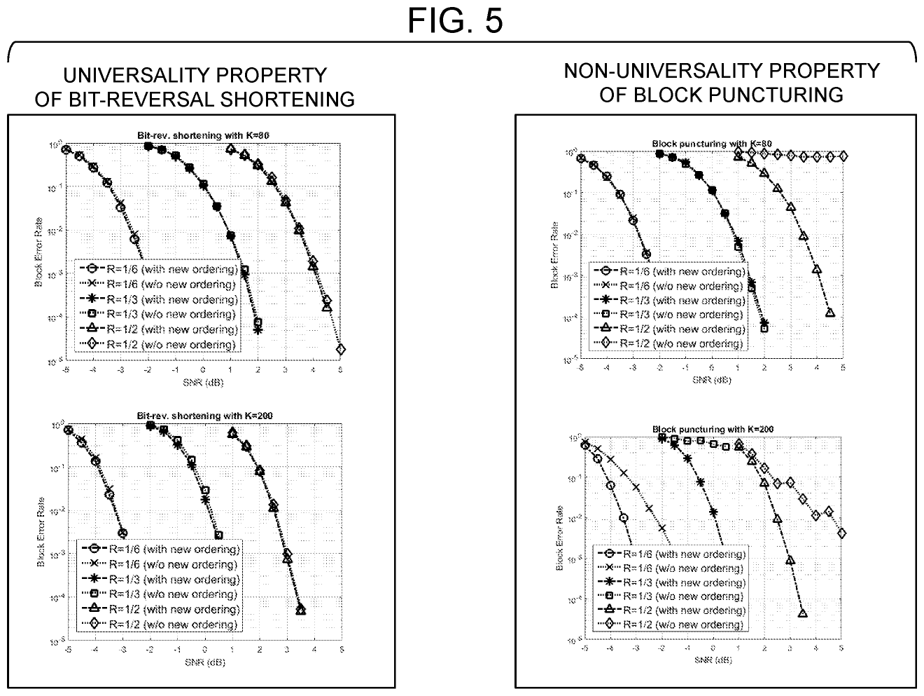

In the case of the bit-reversal shortening, as compared to the block puncturing, the BLER performance is almost the same with redesign as without redesign as illustrated in FIG. 5.

In the case where a bit-reversal shortening pattern is used, a set of N-M indices of a codeword can be skipped from transmission so as to transmit a relatively short-length rate-matched polar code. For one example of the bit-reversal shortening pattern, the last N-M indices (i.e., {N-M+1, . . . , N−1}) of a codeword may be skipped from transmission, where the set of all indices in the codeword is denoted as {0, 1, . . . , N−1}. If a polar encoder of the form

c=uG₂^{⊗n} (Math. 5)

is used, then the bit-reversal permutation of the last N-M indices may be skipped from transmission. Other examples of a bit-reversal shortening pattern are also not precluded.

Next, taking the bit-reversal shortening pattern as an example of the universal rate-matching scheme, an exemplary embodiment of the present invention will be described in detail.

### 3. Exemplary Embodiment

Hereinafter, an exemplary embodiment of the present invention will be discussed in its complete details with accompanying figures. The embodiment described herein is only illustrative of some specific representations of the invention acknowledging the fact that the inventive concepts can be embodied in a wide variety of contexts. Thus the exemplary embodiment does not limit the scope of the present invention.

### 3.1) Sender Device

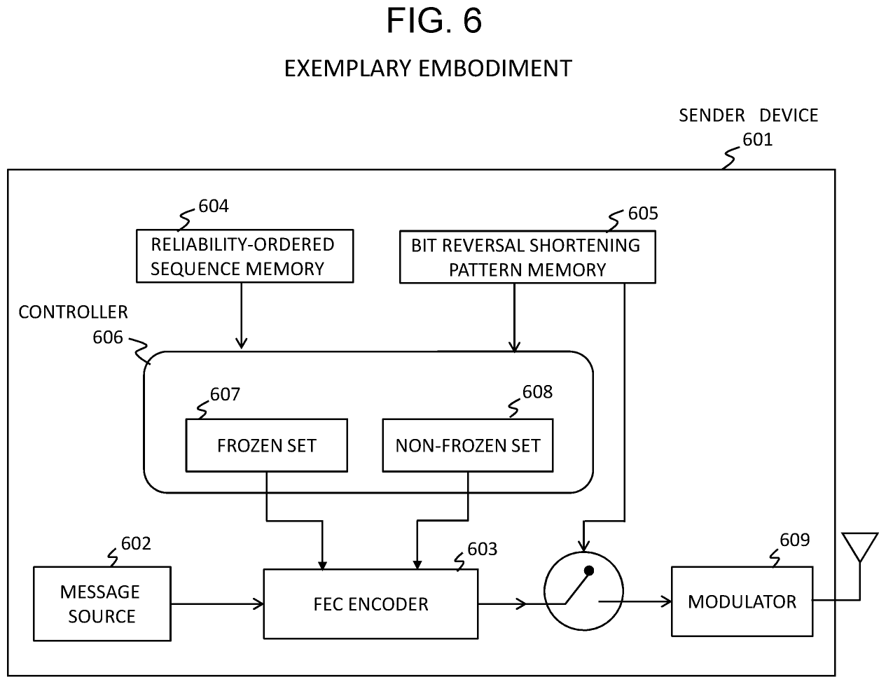

As illustrated in FIG. 6, a sender device 601 is provided with data sending functions including a message source 602, a Forward Error Correction (FEC) encoder 603 of encoding scheme for Polar Codes, a first memory 604 that stores at least one reliability-ordered sequence of indices, a second memory 605 that stores a bit-reversal shortening pattern as a universal rate-matching scheme, and a controller 606 that selects the frozen set 607 and non-frozen set 608 and constructs the input vector for encoding at the FEC encoder 603. The controller 606 or a separate controller may control which bits are skipped from the encoder output by referring to the bit-reversal shortening pattern stored in the second memory 605. In the present exemplary embodiment, the second memory 605 stores a bit-reversal shortening pattern as an example of the universal rate-matching scheme.

The controller 606 uses a frozen set memory 607 and a non-frozen set memory 608 to select or store a frozen set and a non-frozen set of indices using the at least one sequence stored in the first memory 604 and the bit-reversal shortening pattern store in the second memory 605. A modulator 609 modulates the rate-matched polar code and then sends it to a radio-frequency (RF) unit for transmission (not shown). The functions of the sender device 601, including functions of generating the reliability-ordered sequence and the bit-reversal shortening pattern and of the polar code encoding, may be implemented on a processor running respective programs stored in a memory device (not shown).

The message source 602 generates some information bits that need to be encoded and then transmitted. The FEC encoder 603 may encode an input vector u using the following equation:

c=uBG₂^{⊗n} (Math. 6)

where c is a codeword of polar codes, u is input vector to the encoder, B is a N×N bit-reversal permutation matrix, and

G₂^{⊗n} (Math. 7)

is an n-Kronecker product of a polarizing kernel G₂.

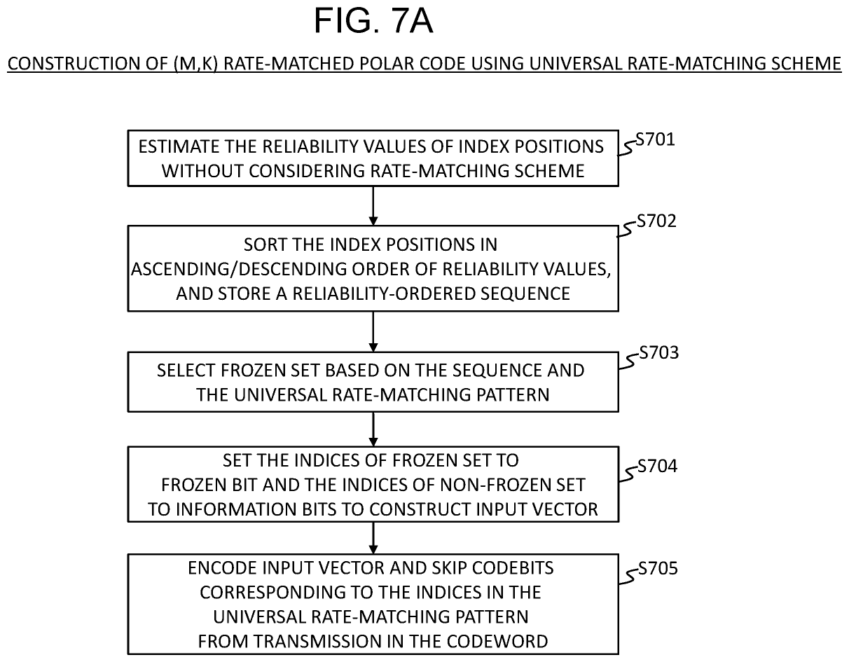

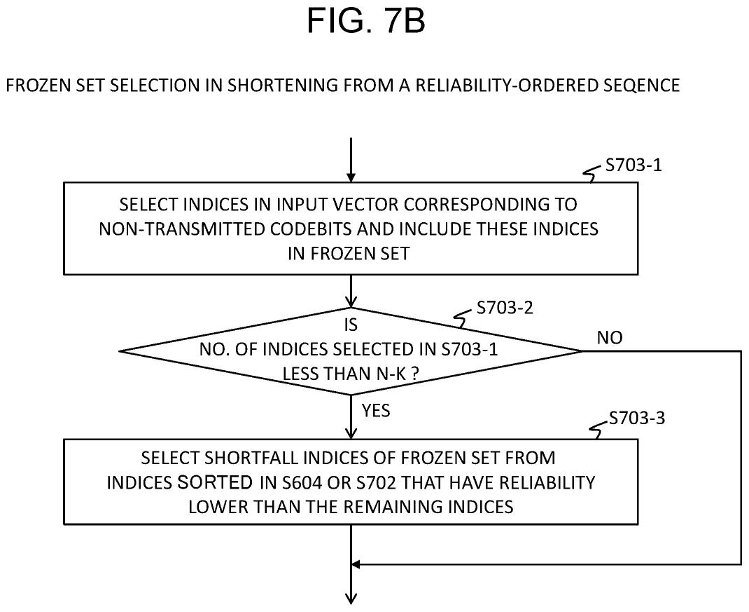

The first memory 604 stores at least one reliability-ordered sequence of indices that is generated without taking into consideration the change in reliability values of indices resulting from rate-matching. Such a reliability-ordered sequence of indices may be generated by estimating the reliability values of the indices (see S701 of FIG. 7A) using a method like DE based on GA. The indices may then be sorted according to their reliability values (see S702 of FIG. 7A) and stored in the first memory 604.

The second memory 605 stores the bit-reversal shortening pattern as a universal rate-matching pattern that can be used to construct a short length polar codes without significantly changing reliability ordering of indices. The bit-reversal shortening pattern may be a set of N-M indices that can be skipped from transmission so as to transmit a relatively short-length rate-matched polar code. For one example of the bit-reversal shortening pattern, the last N-M indices (i.e., {N-M+1, . . . , N−1}) of a codeword may be employed, where the codeword may be denoted as {0, 1, . . . , N−1}.

For bit-reversal shortening, the bit-reversal permuted values of the set of {N-M+1, . . . , N−1} are included in the frozen set 607. The remaining indices of the frozen set 607 may be chosen from the at least one reliability-ordered sequence stored in the first memory 604.

Once the frozen set 607 is completely selected by the controller 606, it can select the non-frozen set 608 as the set difference of {0, 1, . . . , N−1} and the frozen set. The controller 606 can then set information bits (received from message source 602) at the indices contained in the non-frozen set 608 and frozen bits (for e.g., 0) at the indices contained in the frozen set 607 to construct the input vector. The input vector thus designed is fed as input to the FEC encoder 603, which encodes the input vector into a polar codeword. The controller 606 refers to the bit-reversal shortening pattern stored in the second memory 605 for skipping the last N-M indices of the generated codeword from transmission to output a rate-matched polar codeword to the modulator 609. An outline of constructing a rate-matched polar codeword employing a universal rate-matching scheme will be described with reference to FIG. 7.

### 3.2) Construction of Rate-Matched Polar Codes

As illustrated in FIGS. 7A and 7B, an (M, K) rate-matched polar codeword is constructed using a bit-reversal shortening pattern. The reliability value of each index in input vector is estimated using DE based on GA (Operation S701). For instance, the initial LLR values corresponding to the channel outputs which are fed as input to the Density Evolution block may be all set to the same value based on the noise variance, thereby it is possible to estimate a reliability value of each index position in input vector U. Preferably, reliability values of Nₘₐₓ indices are estimated, where Nₘₐₓ is a power of 2. Nₘₐₓ can be greater than, less than or equal to N (a power of 2ⁿ, where n is a ceiling function of log₂ M).

When the reliability value of each index position in the input vector U has been estimated, the N indices of the input vector U are sorted in ascending/descending order of reliability and the resulting reliability-ordered sequence of length N is stored in the first memory 604 (Operation S702). Preferably, a reliability-ordered sequence of length Nₘₐₓ is pre-stored as a reference sequence. A reliability-ordered sequence of any length N can be obtained as an ordered subset from the reference sequence of length Nₘₐₓ.

Subsequently, the controller 606 selects the frozen set 607 from the reliability-ordered sequence stored in the first memory 604 and the bit-reversal shortening (Operation S703). A bit-reversal shortening pattern may be a set of last N-M indices of a codeword, which can be skipped from transmission so as to transmit a relatively short-length rate-matched polar code. For bit-reversal shortening, the bit-reversal permuted values of the set of {N-M+1, . . . , N−1} are included in the frozen set 607. The remaining indices of the frozen set 607 may be chosen from the at least one reliability-ordered sequence stored in the first memory 604. More specifically, such frozen set selection is performed as illustrated in FIG. 7B.

In FIG. 7B, the controller 606 selects indices in the input vector corresponding to the non-transmitted codebits and includes them in the frozen set 607 (Operation S703-1). For example, if bit-reversal shortening scheme is used with an encoder of the form

c=uBG₂^{⊗n}, (Math. 8)

then the last N-M indices of the codeword are not transmitted and the indices obtained by applying bit-reversal permutation on the last N-M indices are set to a known value (e.g., frozen bit) and may be included in frozen set. If the number of indices selected in the S703-1 is less than N-K (Operation S703-2; YES), the controller 606 selects the remaining indices of the frozen set 607 from the indices sorted in the first memory 604 that have relatively low reliability than the remaining indices (Operation S703-3). For instance, the controller 606 includes the bit-reversed permutations of the last N-M indices in the frozen set 607. The remaining of the indices in the frozen set 607 are selected from the reliability-ordered sequence stored in the first memory 604, i.e., indices with least reliability in the reliability-ordered sequence stored in the first memory 604 are included in the frozen set 607 to fill the shortfall indices in frozen set 607.

Referring to FIG. 6 and FIG. 7A, the controller 606 puts information bits generated by the message source 602 in the non-frozen set 608 and the indices in the frozen set 607 are filled with frozen bit (for instance, 0) to construct the input vector U (Operation S704).

The controller 606 provides the resulting input vector U to the FEC encoder 603, which encodes the input vector U to output a codeword. At the output of the encoder, the resulting codeword is controlled so as to skip the codebits corresponding to the indices in the universal rate-matching pattern from transmission (Operation S705).

Further specific details of the many variants discussed above will be explained using the following embodiments supplemented by figures.

### 3.3) Example

An example of how to design a (11, 8) rate-matched polar code using the bit-reversal shortening is as follows:

### Step 1: <Reliability Ordering>

Sort the indices 0, 1, . . . , 2ⁿ−1 (n=a ceiling function of log₂11) in ascending order of reliability-, for example: {0,1,2,4,8,3,5,6,9,10,12,7,11,13,14,15}.

### Step 2: <Select Frozen Set>

Step 2.1: Include the bit-reversal permutation of the last N-M indices {11, 12, 13, 14, 15} in the frozen set, i.e., {13, 3, 11, 7, 15}.

Step 2.2: Since size of frozen set is N-K=16−8=8, hence 8−5=3 more indices have to be selected. These 3 indices can be selected according to the sequence generated in Step1 which are {0, 1, 2}. Thus total frozen set is {0, 1, 2, 3, 7, 11, 13, 15}. These indices are set to frozen bit (e.g., 0). Information bits are put in the remaining indices.

### Step 3: <Encoding>

Multiply with

BG_{2⊗n}. (Math. 9)

As described above, using the universal rate-matching scheme and pattern causes the reliability-ordering of indices without considering rate-matching to be very similar to the reliability-ordering of indices optimized according to the rate-matching. Accordingly, the same sequence can be used both with and without rate-matching. Also, the same sequence can be used to design any length of rate-matched code.

### 3.4) Receiver Device

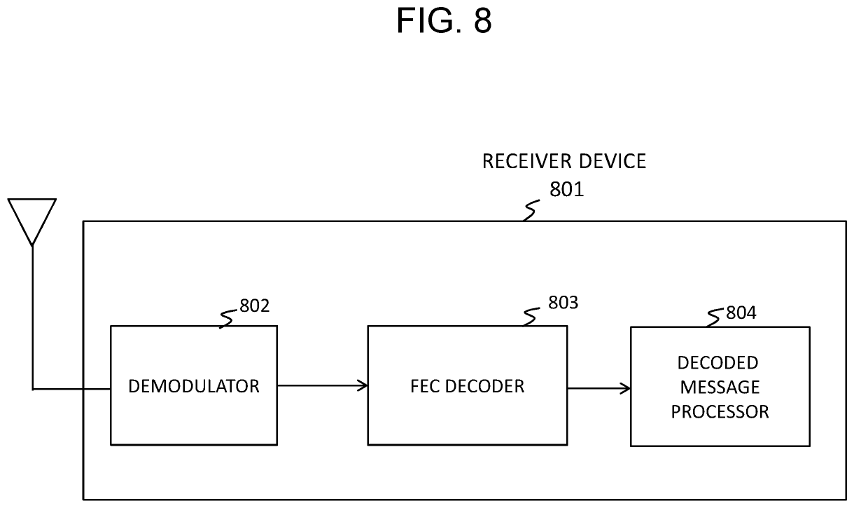

As illustrated in FIG. 8, a receiver device 801 is provided with data receiving functions including a demodulator 802, a FEC decoder 803 and a decoded message processor 804, which may be implemented on a processor running respective programs stored in a memory device (not shown). An LLR vector of length M is constructed from the received vector (i.e., channel output) of length M. Then an LLR vector of length N may be constructed from the LLR vector of length M by filling the indices corresponding to non-transmitted bits by very high value (in case of shortening) or very low value (in case of puncturing). For instance, in case of bit-reversal shortening, the LLR values for the last N-M bits may be set to very high value, assuming that an encoder of the form

BG₂^{⊗n} (Math. 10)

is used. This LLR vector of length N may be fed as input to the decoding algorithm in the FEC decoder 803. The FEC decoder 803 runs a decoding algorithm on the LLR vector to produce a decoded message, which is output to the decoded message processor 804.

### 3.5) Other Applications

A communication device according to the exemplary embodiment of the present invention will be described as a sender device or a receiver device. The sender device and the receiver device may be integrated into a single communication device.

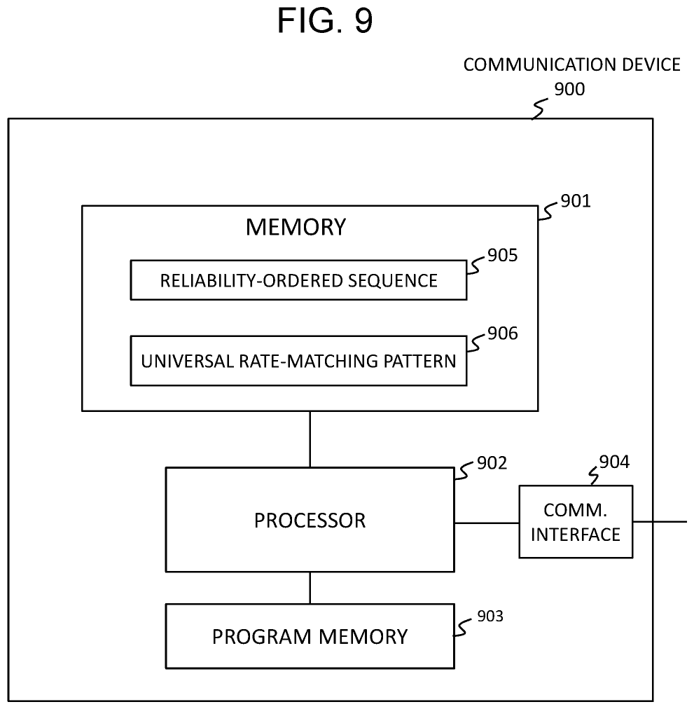

As illustrated in FIG. 9, a communication device 900 may be provided with at least the sender device 601 as shown in FIG. 6. The communication device 900 may contain a memory 901 to store at least one sequence of indices sorted in reliability-ordered sequence 905 and at least one rate-matching pattern 906, a processor 902 consisting of at least one controller which can select frozen and non-frozen sets and do encoding so as to construct a polar codeword as described before. The communication device 900 includes a program memory 903, a communication interface 904, and other units necessary for communication.

The program memory 903 stores computer-readable programs for implementing at least the selection of frozen set 607 and non-frozen set 608, design of input vector to the FEC encoder 603 as shown in FIG. 6. According to the programs stored in the program memory 903, the processor 902 uses the reliability-ordered sequence 905 and the universal rate-matching pattern 906 in the memory 901 to select frozen and non-frozen sets, construct input vector to the polar encoder and output a rate-matched polar codeword to the communication interface 904 as described above.

Where applicable, various embodiments provided by the present disclosure may be implemented using hardware, software, or combinations of hardware and software. Also where applicable, the various hardware components and/or software components set forth herein may be combined into composite components comprising software, hardware, and/or both without departing from the spirit of the present disclosure. Where applicable, the various hardware components and/or software components set forth herein may be separated into sub-components comprising software, hardware, or both without departing from the spirit of the present invention. In addition, where applicable, it is contemplated that software components may be implemented as hardware components, and vice-versa.

Although embodiments of the present disclosure have been described, these embodiments illustrate but do not limit the disclosure. For example, the frozen set may have any constant bit pattern (not restricting to the all-zero pattern) that is known to the decoder in advance. The generator matrix used in polar code encoding can be even of a form other than the n-time Kronecker product of

$${G}_{2} = ( \begin{matrix}1 & 0 \\ 1 & 1\end{matrix} ) . \qquad ( Math . 11 )$$

A different matrix may also be used as polarizing kernel. For example, the following matrix can be used as a different polarizing kernel:

$${G}_{2} = ( \begin{matrix}1 & 0 & 0 \\ 1 & 1 & 0 \\ 1 & 0 & 1\end{matrix} ) . \qquad ( Math . 12 )$$

Shortening may also include setting some input bits to a known value (not limited to zero) such that codebits corresponding to those known input bits can be skipped during transmission. The decoder can set the initial LLR value corresponding to the non-transmitted codebits to very high value.

Encoder of the form

c=uG₂^{⊗n} (Math. 13)

is also not precluded. If a universal shortening scheme is used with such an encoder, then the indices of the non-transmitted codebits in the codeword are selected and set to a known value (e.g., frozen bit) in the input to the encoder. For instance, if a bit-reversal shortening scheme is used with such an encoder, then the bit-reversal permutations of the last N-M indices in the codeword are not transmitted and the same indices are set to a known value (e.g., frozen bit).

In other embodiments, it is possible that only one of a frozen set and non-frozen set is stored in memory, not both. For instance, if the frozen set is stored in memory, then the non-frozen set is automatically known to be the remaining indices other than frozen set in the input vector of length N to the encoder.

Application software in accordance with the present disclosure, such as computer programs executed by the device and may be stored on one or more computer readable mediums. It is also contemplated that the steps identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein.

It should also be understood that embodiments of the present disclosure should not be limited to these embodiments but that numerous modifications and variations may be made by one of ordinary skill in the art in accordance with the principles of the present disclosure and be included within the spirit and scope of the present disclosure as hereinafter claimed.

The above exemplary embodiments can be applied to communication systems employing polar encoding and decoding.

### REFERENCE SIGNS LIST

601 Sender device
602 Message source
603 FEC Encoder
604 first memory (reliability-ordered sequence memory)
605 second memory (bit-reversal shortening pattern memory)
606 Controller
607 Frozen set memory
608 Non-frozen set memory
609 Modulator
901 Receiver device
902 Demodulator
903 Decoder controller
903 FEC Decoder
904 Decoded message processor

1. A communication apparatus comprising:
an encoder that encodes an input vector to output a codeword of polar code;
a memory that stores a reliability-ordered sequence of indices of the input vector and a set of indices for rate-matching;
a controller that is configured to:
select a frozen set of indices based on at least one of a universal rate-matching scheme and the reliability-ordered sequence stored in the memory such that the reliability-ordered sequence is generated without considering the rate-matching scheme;
construct the input vector by setting the frozen set to a frozen bit and a non-frozen set to information bits; and
skip the transmission of those codebits of the codeword outputted by the encoder that correspond respectively to the set of indices for rate-matching.

2. The communication apparatus according to claim 1, wherein the memory previously stores a reference sequence which is a reliability-ordered sequence of a length greater or small or same as that of the reliability-ordered sequence, wherein the reliability-ordered sequence is derived from the reference sequence when their lengths are not same.

3. The communication apparatus according to claim 1, wherein the universal rate-matching scheme is a rate-matching scheme and pattern which satisfies at least one of the following:
It does not change a content of the non-frozen set significantly with and without rate-matching consideration; and
the error correcting performance produced by a rate-matched polar codes encoded using a sequence generated for non-rate-matched polar codes is very similar to that generated using a sequence optimized for the rate-matching scheme.

4. The communication apparatus according to claim 1, wherein a specific rate-matching scheme is one of universal rate-matching schemes on condition that first error correcting performance of a polar code obtained according to reliability values optimized to the specific rate-matching scheme is substantially same as second error correcting performance of a polar code obtained according to reliability values which are generated without considering the specific rate-matching scheme.

5. The communication apparatus according to claim 1, wherein the universal rate-matching scheme is a bit-reversal shortening scheme.

6. The communication apparatus according to claim 5, wherein the bit-reversal shortening scheme is at least one of the following:
the last N-M bits of the codeword are not transmitted and the indices of the input vector to the encoder obtained by bit reversal permutation of the last N-M indices are set to a known value, when the encoder is of the form
c=uBG₂^{⊗n} (Math. 1)
and
the indices of the codeword obtained by bit reversal permutation of the last N-M indices are not transmitted and the indices of the input vector to the encoder obtained by bit reversal permutation of the last N-M indices are set to a known value, when the encoder is of the form
c=uG₂^{⊗n}. (Math. 2)

7. The communication apparatus according to claim 1, wherein the controller is configured to select the frozen set by:
selecting at least N-M indices of the input vector of length N corresponding to N-M codebits that are not transmitted in the rate-matching scheme, ; and
storing the selected N-M indices into the frozen set, wherein N is a length of the polar code before rate-matching and M is a length of the polar code after rate-matching.

8. The communication apparatus according to claim 1, wherein the controller is configured to select the frozen set by:
selecting indices from the input vector which are bit-reversal permutation of the last N-M indices and including them in the frozen set; and
in response to determining that number of indices of the frozen set is smaller than N-K, selecting shortfall indices from the reliability-ordered sequence stored in the memory that have lower reliability than the remaining indices in the memory, where K is number of information bits.

9. The communication apparatus according to claim 7, wherein the controller is configured to:
in response to determining that number of indices of the frozen set is smaller than N-K, select shortfall indices from the reliability-ordered sequence stored in the memory that have lower reliability than the remaining indices in the memory, where K is number of information bits.

10. A rate matching method for a communication apparatus which comprises: an encoder that encodes an input vector to output a codeword of polar code; and a memory that stores a reliability-ordered sequence of indices of the input vector and a set of indices for rate-matching, the method comprising:
selecting a frozen set of indices based on at least one of a universal rate-matching scheme and the reliability-ordered sequence stored in the memory such that the reliability-ordered sequence is generated without considering the rate-matching scheme;
constructing the input vector by setting the frozen set to a frozen bit and a non-frozen set to information bits; and
skipping codebits of the codeword outputted by the encoder from transmission, the codebits corresponding respectively to the set of indices for rate-matching.

11. The rate matching method according to claim 10, wherein the memory previously stores a reference sequence which is a reliability-ordered sequence of a length greater or small or same as that of the reliability-ordered sequence, wherein the reliability-ordered sequence is derived from the reference sequence when their lengths are not same.

12. The rate matching method according to claim 10, wherein the universal rate-matching scheme is a rate-matching scheme and pattern which satisfies at least one of the following:
it does not change a content of the non-frozen set significantly between with and without rate-matching consideration; and
the error correcting performance produced by a rate-matched polar codes encoded using a sequence generated for non-rate-matched polar codes is very similar to that generated using a sequence optimized for the rate-matching scheme.

13. The rate matching method according to claim 10, wherein a specific rate-matching scheme is one of universal rate-matching schemes on condition that first error correcting performance of a polar code obtained according to reliability values optimized to the specific rate-matching scheme is substantially same as second error correcting performance of a polar code obtained according to reliability values which are generated without considering the specific rate-matching scheme.

14. The rate matching method according to claim 10, wherein the universal rate-matching scheme is a bit-reversal shortening scheme.

15. The rate matching method according to claim 14, wherein the bit-reversal shortening scheme is at least one of the following:
the last N-M bits of the codeword are not transmitted and the indices of the input vector to the encoder obtained by bit reversal permutation of the last N-M indices are set to a known value, when the encoder is of the form
c=uBG₂^{⊗n} (Math. 3)
and
the indices of the codeword obtained by bit reversal permutation of the last N-M indices are not transmitted and the indices of the input vector to the encoder obtained by bit reversal permutation of the last N-M indices are set to a known value, when the encoder is of the form
c=uG₂^{⊗n}. (Math. 4)

16. The rate matching method according to claim 10, wherein the frozen set is selected by:
selecting at least N-M indices of the input vector of length N corresponding to N-M codebits that are not transmitted in the rate-matching scheme; and
storing the selected N-M indices into the frozen set, wherein N is a length of the polar code before rate-matching and M is a length of the polar code after rate-matching.

17. The rate matching method according to claim 10, wherein the frozen set is selected by:
selecting indices from the input vector which are bit-reversal permutation of the last N-M indices and including them in the frozen set; and
in response to determining that number of indices of the frozen set is smaller than N-K, selecting shortfall indices from the reliability-ordered sequence stored in the memory that have lower reliability than the remaining indices in the memory, where K is number of information bits.

18. The rate matching method according to claim 16, wherein the frozen set is selected by:
in response to determining that number of indices of the frozen set is smaller than N-K, selecting shortfall indices from the reliability-ordered sequence stored in the memory that have lower reliability than the remaining indices in the memory, where K is number of information bits.

19. A non-transitory recording medium that stores a program for controlling a communication apparatus which comprises: an encoder that encodes an input vector to output a codeword of polar code; and a memory that stores a reliability-ordered sequence of indices of the input vector and a set of indices for rate-matching, the program comprising a set of instructions to:
select a frozen set of indices based on at least one of a universal rate-matching scheme and the reliability-ordered sequence stored in the memory such that the reliability-ordered sequence is generated without considering the rate-matching scheme;
construct the input vector by setting the frozen set to a frozen bit and a non-frozen set to information bits; and
skip codebits of the codeword outputted by the encoder from transmission, the codebits corresponding respectively to the set of indices for rate-matching.
